(19) United States
(12) Patent Application Publication
(10) Pub. No.: US 2003/0133276 A1
(43) Pub. Date: Jul. 17, 2003

(54) Arrangements to improve noise immunity of differential signals

(76) Inventors: Dong Zhong, Chandler, AZ (US); Yuan-Liang Li, Chandler, AZ (US); David G. Figueroa, Mesa, AZ (US)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/046,783

(22) Filed: Jan. 17, 2002

(51) Int. Cl. H05K 7/10; H05K 7/12

(52) U.S. Cl. 361/768

(57) ABSTRACT

Arrangements are used to improve noise immunity of differential signals.

### FIELD

The present invention is directed to arrangements to improve noise immunity of differential signals.

### BACKGROUND

Background and example embodiments of the present invention may be described using the context of processors and pin grid array signal conductor arrangements, but it is submitted at this juncture that practice of the present invention and a scope of the appended claims is not limited thereto.

To operate effectively, electronic systems must address the potential degradation effects of noise on the system's input, output, and internal signals. The margin for allowable deviations in signals caused by noise decreases as the speed and bandwidth of the signals increase. This decrease in the margin of allowable signal deviations will become more critical as the trend for future components is to combine a reduced size with increased capability.

As relevant discussions, noise may be of many different types, e.g., common-mode or single-ended with common-mode noise seen by all system components, and single-ended noise localized. To provide a reference to cancel noise effects, system signals may be referenced to a certain voltage. This voltage, however, which is desired to serve as a stable benchmark, may vary with noise and electromagnetic variations. Noise may result from crosstalk caused by capacitive coupling between adjacent conductive paths. Resultant signal integrity problems may include undesired effects on signal timing, and data corruption for both asynchronous and synchronous signals.

Example processor systems with parallel busing input/output (I/O) protocol have a separate parallel signal to carry information corresponding to each bit. Thusly, sixty-four signals are required to handle sixty-four bits of information. To attempt to satisfy demand for increased capabilities, there is need for a faster signal speed. To accomplish this with parallel busing, an I/O protocol may require an increase in bandwidth by increasing bit width, or alternatively increase the clock frequency. In using such parallel busing protocol, to attain a data rate of 2.5 Gigabits/second may require a sixty-four bit bus with each signal running at approximately 333 MHZ. To achieve this rate without major degradation of signal quality in a parallel busing protocol is very difficult.

To achieve desired signal quality, an alternative processor system protocol may utilize serial I/O. In this alternative, use is made of one differential pair to carry one signal, with two signal traces that are complimentary to each other. This electrical signaling methodology has each control and data signal represented by a voltage differential between corresponding signal lines. Differential signaling is an alternative to single-ended signaling (e.g., in singe-ended signaling all control and data signals are represented by a voltage difference from a common ground). Differential signal design attempts to have each signal in a pair adjust in common to noise variations. Thusly, when one signal in a pair is referenced to its complement, the theoretical common-mode variation between the two signals is zero.

By utilizing this alternative, the differential I/O can run at much faster speed than a system utilizing parallel busing. If the system design makes use of a serial bus the signal transfer can be accomplished with a more minimal number of only one, two or four pair at 2.5 Gigabit/second. Signal problems, however, can still be of impact due to less than ideal noise immunity of a differential signal in it's environment. If the differential signal is adversely affected by noise, the inherent capability noise rejection capability of a differential signaling design is degraded.

With shrinking system size and faster processing, it is essential to address noise effects to ensure signal integrity. As more input and output signal transfers are required, noise problems are enhanced. Needed are arrangements to decrease the impact of noise on signals in an electrical device.

### BRIEF DESCRIPTION OF THE DRAWINGS

The foregoing and a better understanding of the present invention will become apparent from the following detailed description of example embodiments and the claims when read in connection with the accompanying drawings, all forming a part of the disclosure of this invention. While the foregoing and following written and illustrated disclosure focuses on disclosing example embodiments of the invention, it should be clearly understood that the same is by way of illustration and example only and that the invention is not limited thereto. The spirit and scope of the present invention are limited only by the terms of the appended claims.

The following represents brief descriptions of the drawings, wherein:

FIG. 1 is an exploded view of part of an example electronic system including a side view of a sample semiconductor package assembly to be mounted on an example socket layer (top view), such view being useful in gaining a more thorough understanding/appreciation of the present invention;

FIG. 2 is a side view of an example pin and socket useful to gain a more thorough understanding/appreciation of the present invention;

FIG. 3 is a side view of an example disadvantageous pin and socket orientation;

FIG. 4 is top view of a partial socket layer illustrating an example disadvantageous socket orientation;

FIG. 5 is a side view similar to FIG. 3, but showing an example (advantageous) embodiment of the present invention; and

FIG. 6 is a top view similar to FIG. 4, but showing an advantageous orientation of sockets, and corresponding pins.

### DETAILED DESCRIPTION

Before beginning a detailed description of the subject invention, mention of the following is in order. When appropriate, like reference numerals and characters may be used to designate identical, corresponding or similar components in differing figure drawings. Further, in the detailed description to follow, example sizes/models/values/ranges may be given, although the present invention is not limited to the same. Example arbitrary axes (e.g., X-axis, Y-axis and/or Z-axis) and/or example arbitrary column (C) and row (R) may be discussed/illustrated, although practice of embodiments of the present invention is not limited thereto (e.g., differing axes directions may be able to be assigned, and the Cs and Rs may be able to be reversed). Well known power/ground connections to ICs and other components may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., pin and socket spacing) are set forth in order to describe example embodiments of the invention, it should be apparent to one skilled in the art that the invention can be practiced without, or with variation of, these specific details.

In discussion of the figures, reference made to position of a pin, socket, or pair of sockets are in reference to the relative orientation shown in the figures for illustration. The actual orientation in space may be varied (e.g., above and below) or mirrored.

At this point, it is again stressed that the context of the example embodiments described ahead do not limit practice of the present invention or a scope of the appended claims. For example, although example embodiments of the present invention will be described using an example system block diagram of an example processing package, practice of the invention is not limited thereto, i.e., the invention may be able to be practiced with other types of systems, and in other types of environments (e.g., a communication package). Further, practice may be applicable to non-package arrangements, that is, the term “receiving substrate” may be generically used to describe the component (e.g., motherboard) upon which the first component (e.g., semiconductor package, interposer board) is mounted. Finally, example practice of the invention may be applicable to a single component (e.g., integrated electrical board without mounted components).

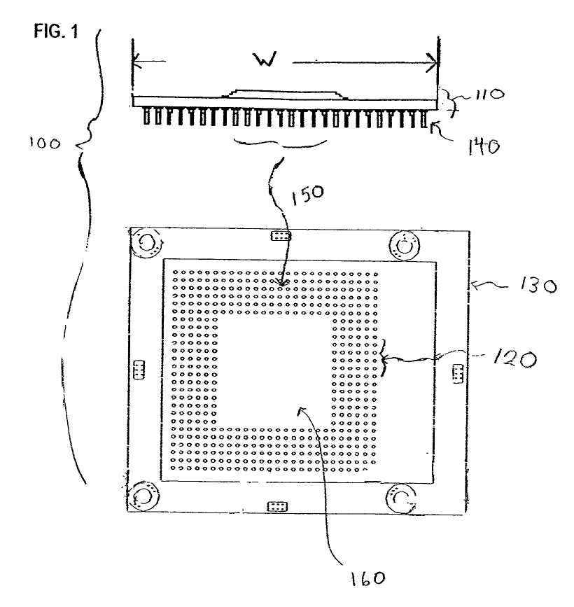

Turning now to a detailed description, FIG. 1 shows an exploded view of part of an example processor system, such view being useful in explanation and understanding of background and example embodiments of the present invention. In particular the view 100 shows an example Flip Chip Pin Grid Array (FCPGA) package assembly 110 which may be subsequently mounted to the socket footprint landing zone 120 of a receiving substrate 130 (e.g., motherboard). An example width W for a FCPGA package assembly is 35 mm. The pins 140 may be seated in the socket openings 150. An example FCPGA package assembly 110 (and corresponding socket openings 150) may be arranged in an example 26 by 26 array with a center cavity gap 160 corresponding approximately in size to a 14 by 14 array (such gap being suitable for mounting optional pin side components (PSC) such as decoupling capacitors). Some example systems may include an intermediate interposer, with a die package assembly attached to the interposer, and the interposer subsequently attached to a receiving substrate (e.g., motherboard).

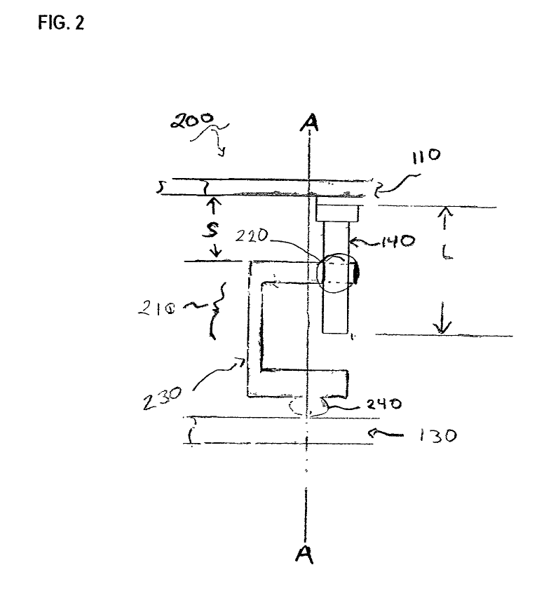

FIG. 2 is a side view representation of an example pin and socket. The side view 200 shows an example pin 140, of the FCPGA package assembly 110, having length L of an example 2.03 mm. The example receiving substrate 130 (e.g., motherboard) example socket 210 is constructed of a base conductive material (e.g., high strength copper alloy). An electrical connection between the socket 210 and pin 140 is at a socket/pin contact area 220. Such example socket/pin contact area has conductive plating over the socket base material (e.g., 07 micron gold over 1.27 micron nickel underplate). The socket/pin contact area 220 may be of a flat geometry as shown in FIG. 2, or alternatively a clamp, prong, or other socket geometry in contact electrically with a pin as long as there is pin-to-socket contact engagement to maintain an acceptable electrical contact. The example FIG. 2 socket 210 shows a socket plate 230 essentially parallel to an axis A with such axis running essentially parallel to the example pin 140, and essentially perpendicular to the surfaces of the receiving substrate 130 (e.g., motherboard), and with the FCPGA package assembly facing each other when assembled.

The sockets 210 may be connected to the receiving substrate 130 (e.g., motherboard) via example solder balls 240 (composed of a tin/lead mixture and of example diameter of 0.508 mm). The example socket height S beneath the FCPGA package assembly may be approximately 3 mm.

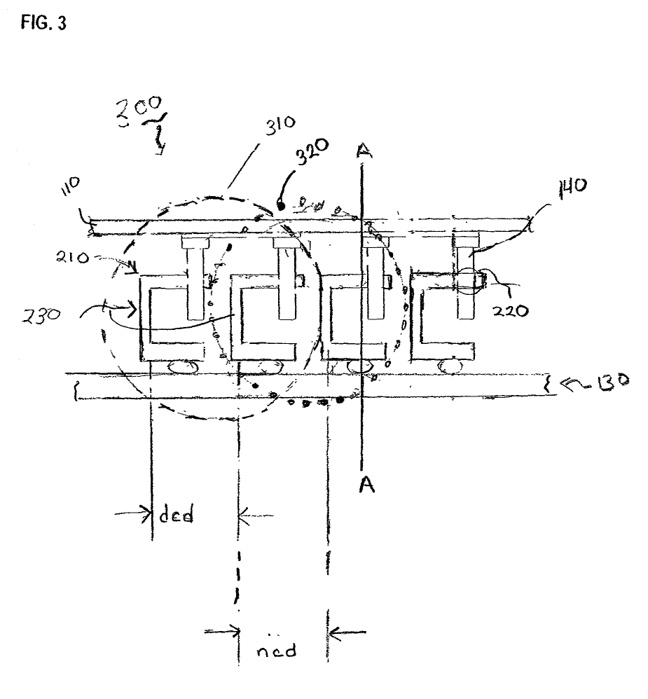

FIG. 3 is a side view representation of sockets contained in an example socket assembly illustrating a disadvantageous orientation. Such side view 300 illustrates four pins 140, with each of the pins in electrical connection with a socket 210 at a socket/pin contact area 220. In a disadvantageous arrangement, all sockets 210 are arranged in essentially a similar orientation (e.g., in reference to the example axis, A). This similar orientation exists regardless of whether two sockets are of an example differential pair 310 (illustrated within dashed-line circle), or two sockets are of an example non-differential pair 320 (shown within a dotted-line circle).

FIG. 3 further shows an example disadvantageous differential pair coupling distance, dcd, between two respective socket plates 230 of pair of sockets which are of an example differential pair 310. Also shown is the disadvantageous non-differential pair coupling distance, ncd, between socket plates 230 of a non-differential pair 320. In the disadvantageous embodiment, this disadvantageous differential pair coupling distance, dcd, may be substantially equal to an example disadvantageous non-differential pair coupling distance, ncd. Such similar socket orientation, and corresponding essentially constant spacing for each pin to socket path may result in the essentially the same degree of coupling occurring between signals in a non-differential pair as between signals that are within a differential pair.

Differential pairs are potentially able to run at a much faster speed because of potential increased noise immunity. Differential pairs carrying one signal have two different modes of the signal, where each mode may be essentially orthogonal to the other. An example may be even mode and odd mode, with the odd mode as a primary signal carrier. In the disadvantageous arrangement, however, there may be no higher degree of coupling between a differential pair, as opposed to between a non-differential pair. This may impact on the ability to distinguish, and thusly reject noise.

Measures of performance of the arrangement may include a degree of system capacitive coupling and inductive coupling. In the disadvantageous arrangement, the substantially similar degree of such coupling between a differential pair and between a non-differential pair may restrict the ability to match impedance through the system. Such coupling arrangement may result in an impedance discontinuity between the receiving substrate 130 (e.g., motherboard) and the FCPGA package assembly. There may be not a substantially matched or continuous impedance though the entirety of the signal path.

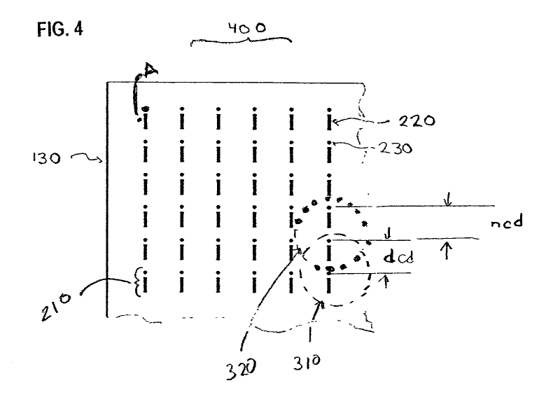

In FIG. 4 is shown a partial top view 400 of an example receiving substrate 130 (e.g., motherboard). Represented are the tops of sockets 210 illustrating a projection of the flat socket/pin contact areas 220, and the tops of socket plates 230. In such a top view, axis A is substantially perpendicular to FIG. 4 (i.e., out of page). Also illustrated are top views of the example differential pair 310 (in dashed circle) and non-differential pair 320 (in dotted circle). As in FIG. 3, the disadvantageous differential pair coupling distance, dcd, between a differential pair 310 may be substantially the same as the disadvantageous non-differential pair coupling distance, ncd, between a non-differential pair 320 of sockets 210. The result from such arrangement may be substantially a similar magnitude of coupling occurring between a differential pair 310 as that occurring between a non-differential pair 320.

Thusly, in such a disadvantageous arrangement, the potential design advantage of utilizing differential signaling may not be realized. Crosstalk, caused by capacitive coupling between adjacent sockets, may cause a change in the delay of a signal or result in an incorrect logic transition between signals in nondifferential pairs. Such socket arrangement may become a weak link in the system design and a bottleneck of the high speed differential signaling. Consequently in such disadvantageous arrangement as a result, desired system performance may not be met.

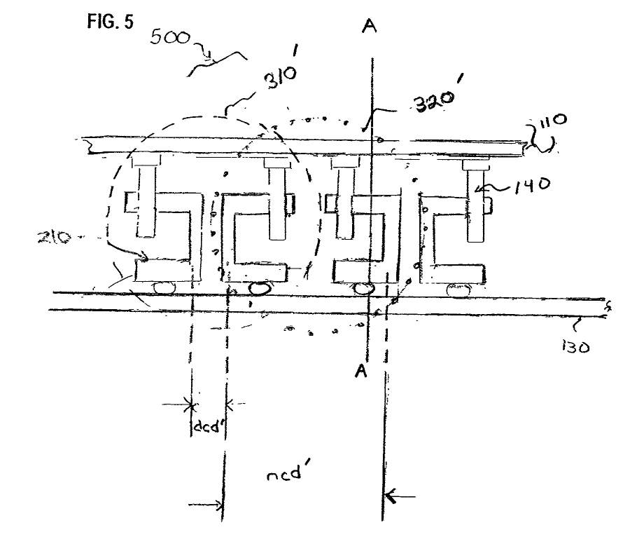

Turning next to FIG. 5 is shown a side view 500 of a pin and socket arrangement illustrating one example (advantageous) embodiment of the present invention. More particularly side view 500 shows an orientation of the sockets 210 so as to potentially increase coupling within a differential pair 310′, while decreasing coupling between a non-differential pair 320′. That is, in each differential pair 310′ of sockets, one of the sockets 210 may be rotated substantially 180 degrees from that shown in the FIGS. 3 and 4 orientation, (e.g., example rotated 180 degrees in respect to axis, a) relative to the other socket member of the differential pair. Such arrangement results in a reduced advantageous differential pair coupling distance, dcd′, and therefore increased coincidence of noise coupled to each member of the differential pair. Because such noise across the pair has increased coincidence, such more mutually common noise can be more successfully removed in differential signal processing. This arrangement also results in an increased advantageous nondifferential pair coupling distance, ncd′.

Stating the above advantages differently, this arrangement increases performance as the capability of the system may be related to the system's ability to reject common mode signals, and may be partially determined by signal carrier spacing. The closer the two signal lines within a differential pair are coupled, the better the common mode rejection. With such advantageous FIG. 5 orientation of the present invention, the immunity of differential signaling arrangements to noise may be enhanced. Simultaneously, coupling and noise crosstalk may be reduced between nondifferential pairs. Noise between non-differential pairs due to crosstalk may be lessened so as to augment signal integrity. With such noise immunity, the ability may be enhanced to reject common mode noise, and other Electromagnetic Interference (EMI).

As further discussion, the amount of crosstalk may be a function of the distance separating the signal paths, and the degree of mutual capacitance and inductance. System performance improves with matched impedance through the signal path. The present invention arrangement of FIG. 5 also may provide an impedance control, as distance between socket plates 230 may determine the differential pair impedance. Such FIG. 5 advantageous arrangement may provide higher capacitive coupling (e.g., 20, 30%), and higher inductive coupling (e.g., 20, 30%) then the disadvantageous arrangements of FIGS. 3 and 4. Consequently, there may be a greater matched impedance through the advantageously arranged system's signal paths than with the FIGS. 3 and 4 arrangement. The potential design benefits of greater noise immunity using differential signaling may be better realized with the present invention arrangement, especially in regards to high-speed I/O application.

As a related aside, increased speed systems may also incorporate corresponding busing systems to transfer the signals. In addition pin spacing, of the example FCPGA package assembly 110 may be altered to correspond more closely with the FIG. 5 arrangement to potentially augment the coupling.

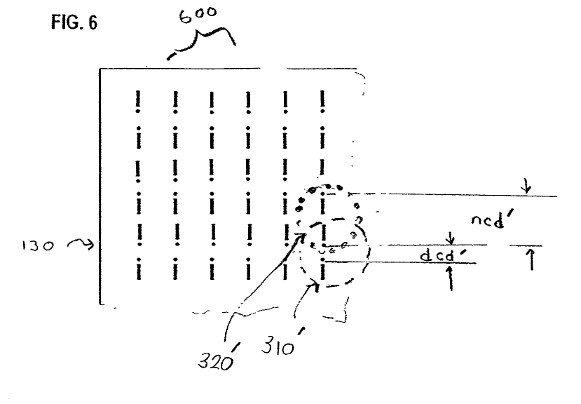

Discussions now turn to FIG. 6 which is a top view 600 of a receiving substrate 130 (e.g., motherboard) similar to FIG. 4, but illustrating an example embodiment of the present invention. Such view 600 illustrates a view at a different perspective angle (top view) as to how in the example advantageous arrangement the advantageous differential coupling distance, dcd′, may be less than advantageous non-differential pair coupling distance, ncd′. Differential signals are closer together so as to potentially increase noise immunity capability. Using increased distance between the nondifferential pairs lessens this trace-to-trace coupling, and reduces crosstalk. This FIG. 6 arrangement may provide necessary noise immunity required for high-speed I/O applications.

In concluding, reference in the specification to one embodiment, an embodiment, or an example embodiment etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments. Furthermore, for ease of understanding, certain method procedures may have been delineated as separate procedures; however, these separately delineated procedures should not be construed as necessarily order dependent in their performance, i.e., some procedures may be able to be performed in an alternative ordering, simultaneously, etc.

This concludes the description of the example embodiments. Although the present invention has been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

For example, with regard to example packages, practice of the present invention is not limited to the above-mentioned FCPGA, and a non-exhaustive listing of other packages may include: micro-Pin Grid Array and Ball Grid Array. In addition the advantageous arrangement may be monolithic or integrated with one component, multiple components, or the assembled components. With regard to the method of electrical conductance between electrical components using sockets and pins, the practice of the present invention is not limited to the FIG. 5 and FIG. 6 objects/features, but instead, other objects/features may likewise be provided. For example, a non-exhaustive listing of further objects/features which can provide signal conduction include wires, or continuous solid surfaces.

What is claimed is:

1. A grid array signal conducting arrangement comprising at least one differential grid array conductor pair and at least one non-differential grid array conductor pair, the at least one differential grid array conductor pair having portions thereof which are more closely spaced in comparison to a spacing of corresponding components in the at least one non-differential grid array conductor pair.

2. A grid array signal conducting arrangement as claimed in claim 1, where the grid array signal conducting arrangement is provided in a grid array connector provided on at least one of a receiving substrate and a semiconductor package.

3. A grid array signal conducting arrangement as claimed in claim 1, where the grid array signal conducting arrangement conducts at least one differential pair signal.

4. A grid array signal conducting arrangement as claimed in claim 3, where the grid array signal conducting arrangement provides at least one of greater coupling and greater common noise between the differential grid array conductor pair than the non-differential grid array conductor pair.

5. A grid array signal conducting arrangement comprising:
at least one differential grid array conductor pair and at least one non-differential g rid array conductor pair; and
means for providing noise rejection capability in the grid array signal conducting arrangement.

6. A grid array signal conducting arrangement as claimed in claim 5, where the grid array signal conducting arrangement is provided in a grid array connector provided on at least one of a receiving substrate and a semiconductor package.

7. A grid array signal conducting arrangement as claimed in claim 5, where the grid array signal conducting arrangement conducts at least one differential pair signal.

8. A grid array signal conducting arrangement as claimed in claim 7, where the grid array signal conducting arrangement provides at least one of greater coupling and greater common noise between the differential grid array conductor pair than the non-differential grid array conductor pair

9. An electrical component comprising:
at least one of a receiving substrate and a semiconductor package; and
a grid array signal conducting arrangement comprising at least one differential grid array conductor pair and at least one non-differential grid array conductor pair, the at least one differential grid array conductor pair having portions thereof which are more closely spaced in comparison to a spacing of corresponding components in the at least one non-differential grid array conductor pair.

10. An electrical component as claimed in claim 9, where the grid array signal conducting arrangement conducts at least one differential pair signal.

11. An electrical component as claimed in claim 10, where the grid array signal conducting arrangement provides at least one of greater coupling and greater common noise between the differential grid array conductor pair than the non-differential grid array conductor pair.

12. A mounted electrical component arrangement comprising:
a plurality of electrical components; and
a grid array signal conducting arrangement comprising at least one differential grid array conductor pair and at least one non-differential grid array conductor pair, the at least one differential grid array conductor pair having portions thereof which are more closely spaced in comparison to a spacing of corresponding components in the at least one non-differential grid array conductor pair.

13. A mounted electrical component arrangement as claimed in claim 12, where the grid array signal conducting arrangement is provided in a grid array connector provided on at least one of a receiving substrate and a semiconductor package.

14. A mounted electrical component arrangement as claimed in claim 12, where the grid array signal conducting arrangement conducts at least one differential pair signal.

15. A mounted electrical component arrangement as claimed in claim 14, where the grid array signal conducting arrangement provides at least one of greater coupling and greater common noise between the differential grid array conductor pair than the non-differential grid array conductor pa

16. A method of increasing noise rejection capability of a grid array signal conducting arrangement comprising:
orientating electrical conductive parts in the grid array signal conducting arrangement that conduct differential signals so as coupling distance between at least one pair of differential signals is less than coupling distance between at least one pair of non-differential signals; and
conducting at least one pair of differential signals through the electrical conductive parts.

17. A method as claimed in claim 16, where the grid array signal conducting arrangement is provided in a grid array connector provided on at least one of a receiving substrate and a semiconductor package.
